(19) United States
(12) Patent Application Publication
(10) Pub. No.: US 2021/0088856 A1
(43) Pub. Date: Mar. 25, 2021

(54) ELECTROSTATIC DISCHARGE UNIT, ARRAY SUBSTRATE AND LIQUID CRYSTAL DISPLAY PANEL

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventor: Wenying LI, Shenzhen, Guangdong (CN)

(21) Appl. No.: 16/314,706

(22) PCT Filed: Sep. 15, 2018
(86) PCT No.: PCT/CN2018/105879

§ 371 Date: Jan. 2, 2019

(30) Foreign Application Priority Data
Aug. 16, 2018 (CN) 201810934549.6

(51) Int. Cl. G02F 1/1362; G02F 1/1368; H01L 27/02; H02H 9/04

(52) U.S. Cl. CPC G02F 1/136204; G02F 1/1368; G02F 1/136286; H01L 27/124; H01L 27/0266; H02H 9/044; H01L 27/0292

(57) ABSTRACT

The embodiment of the present invention provides an electrostatic discharge unit, wherein the electrostatic discharge unit is located an array substrate of a liquid crystal display panel, and comprising: a first branch including at least one first dual gate thin film transistor; a second branch including at least one second dual gate thin film transistor; wherein the first branch and the second branch are connected in parallel, a common first end point is electrically connected to a protection circuit, a common second end point is electrically connected to a common electrode line, and conduction directions of the first dual gate thin film transistor and the second dual gate thin film transistor are opposite. The embodiment of the invention also discloses an array substrate and a liquid crystal display panel. The invention has the advantages of facilitating the realization of the narrow frame of the liquid crystal display panel.

### CROSS-REFERENCE TO RELATED APPLICATION

This application claims the priority of Chinese Patent Application No. 201810934549,6, entitled “ELECTROSTATIC DISCHARGE UNIT, ARRAY SUBSTRATE AND LIQUID CRYSTAL DISPLAY PANEL”, filed on Aug. 16, 2018, the disclosure of which is incorporated herein by reference in its entirety.

### FIELD OF THE INVENTION

The present invention relates to a display technology field, and more particularly to an electrostatic discharge unit, an array substrate and a liquid crystal display panel.

### BACKGROUND OF THE INVENTION

The liquid crystal display panel has become a display panel of a mobile communication device, PC, TV, etc., because of its high display quality, low price, and convenient carrying. Currently, the liquid crystal display panel is generally formed by an array substrate, a color filter substrate, and an intermediate liquid crystal layer.

In the production process of a liquid crystal display panel, static electricity is generated in processes such as drying, etching, alignment film rubbing, cutting, and handling. In order to prevent damage of the display panel by static electricity, an electrostatic discharge circuit is usually provided, for example, on the array substrate of the liquid crystal display panel to release a high voltage level generated by static electricity accumulation.

FIG. 1 is a schematic diagram of a peripheral circuit of a liquid crystal display panel. Referring to FIG. 1, in order to prevent electrostatic damage of the liquid crystal display panel during production and normal operation, ESD (Electro-Static discharge) circuit 110 is placed on the top, bottom, left, and right of the liquid crystal display panel. With the development of liquid crystal display panel technology, people have put forward higher requirements on the display quality and design of liquid crystal display panels. A narrow frame has become the goal pursued by people, while the electrostatic discharge circuit 110 the top, bottom, left, and right of the liquid crystal display panel needs to occupy a large space, which is not conducive to the realization of the narrow frame of the liquid crystal display panel.

### SUMMARY OF THE INVENTION

The technical problem to be solved by the embodiments of the present invention is to provide an electrostatic discharge unit, an array substrate, and a liquid crystal display panel. The space occupied by the electrostatic discharge unit can be reduced, which is beneficial to the realization of the narrow frame of the liquid crystal display panel.

In order to solve the above technology problem, a first aspect of the present invention provides an electrostatic discharge unit, wherein the electrostatic discharge unit is located an array substrate of a liquid crystal display panel, and comprising: a first branch including at least one first dual gate thin film transistor; a second branch including at least one second dual gate thin film transistor; wherein the first branch and the second branch are connected in parallel, a common first end point is electrically connected to a protection circuit, a common second end point is electrically connected to a common electrode line, and conduction directions of the first dual gate thin film transistor and the second dual gate thin film transistor are opposite.

In an embodiment of the first aspect of the invention, each first dual gate thin film transistor includes two first gates, one first semiconductor layer, one first source, and one first drain; on a longitudinal section, the first source, the first drain and the first semiconductor layer are located between the two first gates, and the two first gates and the first source of the same first dual gate thin film transistor are electrically connected together.

In an embodiment of the first aspect of the invention, each of the second dual gate thin film transistors includes two second gates, one second semiconductor layer, one second source and one second drain; on a longitudinal section, the second source, the second drain, and the second semiconductor layer are located between the two second gates, and the two second gates and the second source of a same second dual gate thin film transistor are electrically connected together.

In an embodiment of the first aspect of the invention, the first branch includes multiple first dual gate thin film transistors, the multiple first dual gate thin film transistors are connected in series, a first drain of a previous first dual gate thin film transistor and a first source of a next first dual gate thin film transistor are electrically connected; or the second branch includes multiple second dual gate thin film transistors, the multiple second dual gate thin film transistors are connected in series, a second drain of a previous second dual gate thin film transistor and a second source of a next second dual gate thin film transistor are electrically connected.

In an embodiment of the first aspect of the invention, from the first end point, a first source of a first of the multiple first dual gate thin film transistors is electrically connected to the first end point, and a first drain of a last first dual gate thin film transistor is electrically connected to the second end point, a second drain of a first second dual gate thin film transistor is electrically connected to the first end point, and a second source of a last second dual gate thin film transistor is electrically connected to the second end point.

In an embodiment of the first aspect of the invention, the first gate and the first source of a same first dual gate thin film transistor are electrically connected through digging a hole; the second gate and the second source of a same second dual gate thin film transistor are electrically connected through digging a hole.

In an embodiment of the first aspect of the invention, the two first gates are an upper first gate and a lower first gate, the first dual gate thin film transistor further includes a lower first gate insulation layer and an upper first gate insulation layer, and the lower first gate is deposited on a substrate of the array substrate, the lower first gate insulation layer is formed above the lower first gate, the lower first gate insulation layer covers the lower first gate, and the first semiconductor layer is formed above the lower first gate insulation layer, and a projection of the first semiconductor layer and a projection of the lower first gate are overlapped at a horizontal plane, the first source and the first drain are located above the first semiconductor layer and are respectively located at two sides of the lower first gate, and the first source and the first drain are disposed oppositely, the upper first gate insulation layer is formed above the first source, the first drain, the first semiconductor layer, and the lower first gate insulation layer, the upper first gate is located above the upper first gate insulation layer, and the upper first gate and the lower first gate are directly opposite to each other.

In an embodiment of the first aspect of the invention, the two second gates are an upper second gate and a lower second gate, the second dual gate thin film transistor further includes a lower second gate insulation layer and an upper second gate insulation layer, and the lower second gate is deposited on the substrate of the array substrate, the lower second gate insulation layer is formed above the lower second gate, and the second semiconductor layer is formed above the lower second gate insulation layer, and projections of the second semiconductor layer and the lower second gate at a horizontal plane are overlapped, the second source and the second drain are located above the second semiconductor layer and are respectively located at two sides of the lower second gate, the two upper gate insulation layers are formed above the second source, the second drain, the second semiconductor layer, and the lower second gate insulation layer, the second gate is located above the upper second gate insulation layer, and the upper second gate and the lower second gate are directly opposite to each other.

A second aspect of the present invention provides an array substrate, comprising: multiple scanning lines, and the multiple scanning lines are extended along a first direction; multiple data lines, and the multiple data lines are extended along a second direction which is perpendicular to the first direction; multiple common electrode lines, and the multiple common electrode lines are connected together; multiple electrostatic discharge units, and the electrostatic discharge unit is the above electrostatic discharge unit.

A third aspect of the present invention provides a liquid crystal panel, including the above array substrate.

Embodiments of the present invention have the following beneficial effects:

when there is relatively large static electricity on the protection circuit, the two first gates of the first dual gate thin film transistor on the first branch are turned on, and the first dual gate thin film transistor is turned on, and the static electricity on the protection circuit is quickly transmitted to the common electrode line via the first branch to realize the release of static electricity. Similarly, when there is relatively large static electricity on the common electrode line, the static electricity can be quickly released through the second branch to realize the two-way discharge of static electricity, which can prevent the liquid crystal display panel from being damaged by static electricity during production and normal operation; Moreover, since the first dual gate thin film transistor and the second dual gate thin film transistor each have two gates, the first dual gate thin film transistor and the second dual gate thin film transistor have strong conduction ability. Under the same conduction capability, the first dual gate thin film transistor and the second dual gate thin film transistor have a smaller volume, which can reduce the space occupied by the electrostatic discharge unit occupying the array substrate, and facilitate the liquid crystal display panel to realize a narrow bezel: and the static electricity of the embodiment of the invention The release unit costs less and the process is relatively simple.

### BRIEF DESCRIPTION OF THE DRAWINGS

In order to more clearly illustrate the technical solution in the present invention or in the prior art, the following will illustrate the figures used for describing the embodiments or the prior art. It is obvious that the following figures are only some embodiments of the present invention. For the person of ordinary skill in the art without creative effort, it can also obtain other figures according to these figures.

FIG. 1 is a schematic diagram of a peripheral circuit of a conventional liquid crystal display panel.

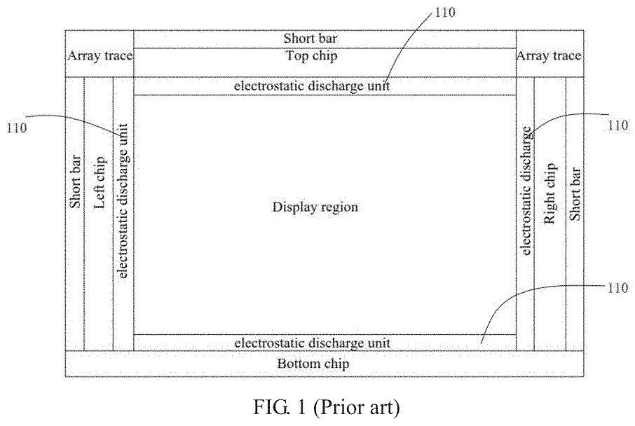

FIG. 2 is a circuit diagram of an electrostatic discharge unit according to an embodiment of the present invention.

FIG. 3 is a cross-sectional view showing a first dual gate thin film transistor (second dual gate thin film transistor) according to an embodiment of the present invention.

### REFERENCE NUMERAL

110—electrostatic discharge circuit; 200—first branch; 210—first dual gate thin film transistor; 211—first gate; 212—first source; 213—first drain; 214—lower first gate insulation layer; 215—upper first gate insulation layer; 216—first semiconductor layer; 300—second branch; 310—second dual gate thin film transistor; 311—second gate; 312—second source 313—second drain; 314—lower second gate insulation layer; 315—upper second gate insulation layer; 316—second semiconductor layer; 410—protected circuit; 420—common electrode line; first end point; 440—second end point; 510—substrate.

### DETAILED DESCRIPTION OF PREFERRED EMBODIMENTS

The following content combines with the drawings and the embodiment for describing the present invention in detail. It is obvious that the following embodiments are only some embodiments of the present invention. For the person of ordinary skill in the art without creative effort, the other embodiments obtained thereby are still covered by the present invention.

The terms “comprising” and “having”, and any variations thereof, appearing in the specification, the claims, and the drawings are intended to cover a non-exclusive inclusion. For example, a process, method, system, product, or device that comprises a series of steps or units is not limited to the listed steps or units, but optionally also includes steps or units not listed, or, optionally, other steps or units inherent to these processes, methods, products or equipment. Moreover, the terms “first,” “second,” and “third,” etc. are used to distinguish different objects, and are not intended to describe a particular order.

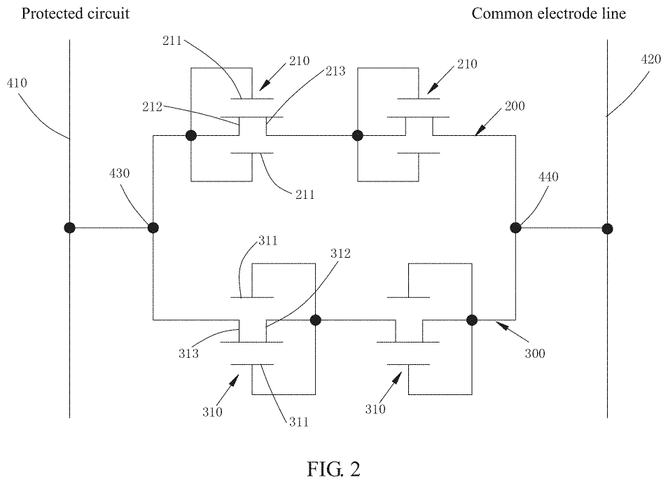

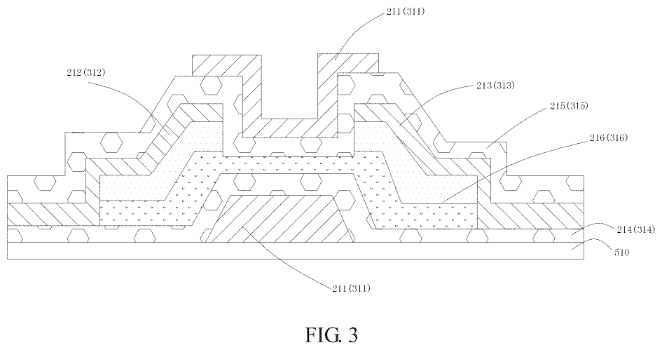

An embodiment of the present invention provides an electrostatic discharge unit, and the discharge unit is located on an array substrate of a liquid crystal display panel. Referring to FIG. 2 and FIG. 3, the electrostatic discharge unit includes a first branch 200 and a second branch 300.

In this embodiment, the first branch 200 includes at least one first dual gate thin film transistor 210, here, the first branch 200 includes two first dual gate thin film transistors 210. Of course, in other embodiments of the invention, the first branch may further include one first dual gate thin film transistor or more than two first dual gate thin film transistors. In this embodiment, each first dual gate thin film transistor 210 includes two first gates 211, a first semiconductor layer 216, a first source 212, and a first drain 213. Wherein the first source 212 and the first drain 213 are located in a same layer, and the first source 212, the first drain 213 and the first semiconductor layer 216 are located between the two first gates 211.

Specifically, in this embodiment, referring to FIG. 3, for each of the first dual gate thin film transistors 210, the two first gates 211 are an upper first gate 211 and a lower first gate 211. The first dual gate thin film transistor further includes a lower first gate insulation layer 214 and an upper first gate insulation layer 215, and the lower first gate 211 is deposited on a substrate 510 of the array substrate, the lower first gate a first insulation layer 214 is formed above the lower first gate 211, the lower first gate insulation layer 214 covers the lower first gate 211, and the first semiconductor layer 216 is formed above the lower first gate insulation layer 214, and a projection of the first semiconductor layer 216 and a projection of the lower first gate 211 are overlapped at a horizontal plane.

The first source 212 and the first drain 213 are located above the first semiconductor layer 216 and are respectively located at two sides of the lower first gate 211, and the first source 212 and the first drain 213 are disposed oppositely. The upper first gate insulation layer 215 is formed above the first source 212, the first drain 213, the first semiconductor layer 216, and the lower first gate insulation layer 214. The upper first gate 211 is located above the upper first gate insulation layer 215, and the upper first gate 211 and the lower first gate 211 are directly opposite to each other.

In this embodiment, the two first gates 211 and the first source 212 of the same first dual gate thin film transistor 210 are electrically connected together. Specifically, the first gate 211 and the first source 212 of a same first dual gate thin film transistor 210 are electrically connected through digging a hole.

In this embodiment, referring to FIG. 2, an end point of a left end of the first branch 200 is referred to as a first end point 430, and an end point of a right end of the first branch 200 is referred to as a second end point 440, on the first branch 200, two first dual gate thin film transistors 210 are disposed, that is, two first dual gate thin film transistors 210 are located between the first end point 430 and the second end point 440, and the two first dual gate thin film transistors 210 are connected in series. Specifically, from the first end point 430, a first drain 213 of a previous first dual gate thin film transistor 210 and a first source 212 (a first gate 211) of a next first dual gate thin film transistor 210 are electrically connected. In addition, in other embodiments of the present invention, when the first branch includes more first dual gate thin film transistors, the multiple first dual gate thin film transistors are connected in series on the first branch, and the first drain of the previous first dual gate thin film transistor is electrically connected to the first source (first gate) of the adjacent next first dual gate thin film transistor.

In this embodiment, the second branch 300 includes at least one second dual gate thin film transistor 310, where the second branch 300 includes two second dual gate thin film transistors 310. Of course, in other embodiments of the invention, the second branch may further include one second dual gate thin film transistor or more than two second dual gate thin film transistors. In addition, in other embodiments of the present invention, the number of the first dual gate thin film transistors included in the first branch may be the same as or different from the number of the second dual gate thin film transistors included in the second branch. In this embodiment, each of the second dual gate thin film transistors 310 includes two second gates 311, one second semiconductor layer 310, one second source 312, and one second drain 313. The second source 312 and the second drain 313 are located in the same layer, and the second source 312, the second drain 313, and the second semiconductor layer 316 are located between the two second gates 311

Specifically, in this embodiment, referring to FIG. 3, for each of the second dual gate thin film transistors 310, the two second gates 311 are an upper second gate 311 and a lower second gate 311, the second dual gate thin film transistor further includes a lower second gate insulation layer 314 and an upper second gate insulation layer 315. In this embodiment, the lower second gate insulation layer 314 and the lower upper first gate insulation layer 214 are the same layer, the upper second gate insulation layer 315 and the upper first gate insulation layer 215 are the same layer, and the lower second gate 311 is deposited on the substrate 510 of the array substrate. The lower second gate insulation layer 314 is formed above the lower second gate 311, the lower second gate insulation layer 314 covers the lower second gate 311, and the second semiconductor layer 316 is formed above the lower second gate insulation layer 314, and projections of the second semiconductor layer 316 and the lower second gate 311 at a horizontal plane are overlapped.

The second source 312 and the second drain 313 are located above the second semiconductor layer 316 and are respectively located at two sides of the lower second gate 311, and the second source 312 and the second drain 313 are opposite. The two upper gate insulation layers 315 are formed above the second source 312, the second drain 313, and the second semiconductor layer 316, and the lower second gate insulation layer 314. The second gate 311 is located above the upper second gate insulation layer 315, and the upper second gate 311 and the lower second gate 311 are directly opposite to each other.

In this embodiment, the two second gates 311 and the second source 312 of a same second dual gate thin film transistor 310 are electrically connected together. Specifically, the second gate 311 and the second source 312 of a same second dual gate thin film transistor 310 are electrically connected by digging a hole.

In this embodiment, please continue to refer to FIG. 2, the second branch 300 is connected in parallel with the first branch 200, and the connection point between the second branch 300 and the left end of the first branch 200 is the first end point 430, the connection point between the second branch 300 and the right end of the first branch 200 is the second end point 440, and the second branch 300 is provided with two second dual gate thin film transistors 310, that is, the two dual gate thin film transistors 310 are located between the first end point 430 and the second end point 440, and the two second dual gate thin film transistors 310 are connected in series. Specifically, from the first end point 430, a previous second source 312 (second gate 311) of the second dual gate thin film transistor 310 is electrically connected to a second drain 313 of a next second dual gate thin film transistor 310. In addition, in other embodiments of the present invention, when the second branch includes more second dual gate thin film transistors, a plurality of the second dual gate thin film transistors are connected in series on the second branch, and a previous second source (second gate) of a second dual gate thin film transistor is electrically connected to a second drain of an adjacent next second dual gate thin film transistor.

In this embodiment, the common first end point 430 of the left terminal of the first branch 200 and the second branch 300 is electrically connected to a protected circuit 410, for example, the scanning line or/and the data line on the array substrate. The common second end point 440 of the right terminal of the first branch 200 and the second branch 300 is electrically connected to a common electrode line 420 (Com line). A plurality of common electrode lines 420 are disposed on the array substrate, and all of the common electrode lines 420 are electrically connected together to reduce the influence of the discharged static electricity on the voltage on the common electrode line 420. In this embodiment, the first dual gate thin film transistor 210 and the second dual gate thin film transistor 310 have opposite conduction directions. In FIG. 2, the conduction direction of the first dual gate thin film transistor 210 is from left to right, the conduction direction of the second dual gate thin film transistor 310 is from right to left, and of course, the reverse is also possible.

In this embodiment, when there is relatively large static electricity on the protected circuit 410, the two first gates 211 of the first dual gate thin film transistor 210 on the first branch 200 are turned on, and the first dual gate thin film transistor 210 is turned on, and the static electricity on the protected circuit 410 is quickly transmitted to the common electrode line 420 via the first branch 200 to realize the release of static electricity. Similarly, when there is relatively large static electricity on the common electrode line 420, the static electricity can be quickly released through the second branch 300 to realize the two-way discharge of static electricity, which can prevent the liquid crystal display panel from being damaged by static electricity during production and normal operation;

Moreover, since the first dual gate thin film transistor 210 and the second dual gate thin film transistor 310 each have two gates, the first dual gate thin film transistor 210 and the second dual gate thin film transistor 310 have strong conduction ability. Under the same conduction capability, the first dual gate thin film transistor 210 and the second dual gate thin film transistor 310 have a smaller volume, which can reduce the space occupied by the electrostatic discharge unit occupying the array substrate, and facilitate the liquid crystal display panel to realize a narrow frame; and the electrostatic discharge unit of the embodiment of the invention has less cost and the process is relatively simple.

In this embodiment, the materials of the first semiconductor layer 216 and the second semiconductor layer 316 are amorphous silicon, IGZO or polysilicon.

In addition, an embodiment of the present invention further provides an array substrate, wherein the array substrate includes a plurality of scanning lines, a plurality of data lines, a plurality of common electrode lines, and a plurality of electrostatic discharge units. Wherein the plurality of scanning lines extend in a first direction, for example, in a lateral direction; the plurality of data lines extend in a second direction, for example, extending in a longitudinal direction, the second direction is perpendicular to the first direction; The multiple common electrode lines are electrically connected together; the electrostatic discharge unit is the above-mentioned electrostatic discharge unit. In this embodiment, the electrostatic discharge unit may be located on the top side, the bottom side, the left side, the right side, and the like of the array substrate.

In this embodiment, the protected circuit is the scanning line or/and the data line. When the scanning line or the data line exist the static electricity, the static electricity on the scanning line or the data line is released to the common electrode line, since the common electrode lines are electrically connected to each other, the static electricity is released to all the common electrode lines, and the voltage on the common electrode line does not cause fluctuations.

When only one of the electrostatic discharge units is electrically connected to a certain electrostatic discharge unit, when the electrostatic discharge unit is damaged, for example, when the first branch is disconnected, at this time, the static electricity on the protected line cannot be discharged through the electrostatic discharge unit. In order to prevent this problem from occurring, in this embodiment, the same protection circuit is electrically connected to a plurality of the electrostatic discharge units, for example, two, three, four or more electrostatic discharge units are electrically connected to the same protected circuit, so that when one of the electrostatic discharge units is damaged, the protected circuit can also discharge static electricity through other electrostatic discharge units, thereby improving the safety of the static electricity protection.

In this embodiment, the array substrate further includes a gate driver, and the gate driver is located on the substrate of the array substrate, that is, the commonly described GOA technology, which can further facilitate the narrow frame of the liquid crystal display panel. In this embodiment, the gate driver is electrically connected to the plurality of scanning lines, respectively, and if the scanning line is electrically connected to the electrostatic discharge unit, the electrostatic discharge unit is located inside the gate driver.

The embodiment of the invention further provides a liquid crystal display panel, wherein the liquid crystal display panel comprises the above array substrate. In this embodiment, the liquid crystal display panel includes a display region and a non-display region, and the electrostatic discharge unit is located in the non-display region.

It should be noted that the various embodiments in the present specification are described in a progressive manner, and each embodiment focuses on differences from other embodiments, and the same similar parts between the various embodiments are mutually referred. For the device embodiment, since it is basically similar to the method embodiment, the description is relatively simple, and the relevant parts can be referred to the description of the method embodiment.

The above is only the preferred embodiment of the present invention, and the scope of the present invention is not limited thereto, and thus equivalent changes made in the claims of the present invention are still within the scope of the present invention.

What is claimed is:

1. An electrostatic discharge unit, wherein the electrostatic discharge unit is located an array substrate of a liquid crystal display panel, and comprising:
a first branch including at least one first dual gate thin film transistor;
a second branch including at least one second dual gate thin film transistor;
wherein the first branch and the second branch are connected in parallel, a common first end point is electrically connected to a protection circuit, a common second end point is electrically connected to a common electrode line, and conduction directions of the first dual gate thin film transistor and the second dual gate thin film transistor are opposite.

2. The electrostatic discharge unit according to claim 1, wherein each first dual gate thin film transistor includes two first gates, one first semiconductor layer, one first source, and one first drain; on a longitudinal section, the first source, the first drain and the first semiconductor layer are located between the two first gates, and the two first gates and the first source of the same first dual gate thin film transistor are electrically connected together.

3. The electrostatic discharge unit according to claim 2, wherein each of the second dual gate thin film transistors includes two second gates, one second semiconductor layer, one second source and one second drain; on a longitudinal section, the second source, the second drain, and the second semiconductor layer are located between the two second gates, and the two second gates and the second source of a same second dual gate thin film transistor are electrically connected together.

4. The electrostatic discharge unit according to claim 3, wherein the first branch includes multiple first dual gate thin film transistors, the multiple first dual gate thin film transistors are connected in series, a first drain of a previous first dual gate thin film transistor and a first source of a next first dual gate thin film transistor are electrically connected; or
the second branch includes multiple second dual gate thin film transistors, the multiple second dual gate thin film transistors are connected in series, a second drain of a previous second dual gate thin film transistor and a second source of a next second dual gate thin film transistor are electrically connected.

5. The electrostatic discharge unit according to claim 3, wherein from the first end point, a first source of a first of the multiple first dual gate thin film transistors is electrically connected to the first end point, and a first drain of a last first dual gate thin film transistor is electrically connected to the second end point, a second drain of a first second dual gate thin film transistor is electrically connected to the first end point, and a second source of a last second dual gate thin film transistor is electrically connected to the second end point.

6. The electrostatic discharge unit according to claim 3, wherein the first gate and the first source of a same first dual gate thin film transistor are electrically connected through digging a hole; the second gate and the second source of a same second dual gate thin film transistor are electrically connected through digging a hole.

7. The electrostatic discharge unit according to claim 2, wherein the two first gates are an upper first gate and a lower first gate, the first dual gate thin film transistor further includes a lower first gate insulation layer and an upper first gate insulation layer, and the lower first gate is deposited on a substrate of the array substrate, the lower first gate insulation layer is formed above the lower first gate, the lower first gate insulation layer covers the lower first gate, and the first semiconductor layer is formed above the lower first gate insulation layer, and a projection of the first semiconductor layer and a projection of the lower first gate are overlapped at a horizontal plane, the first source and the first drain are located above the first semiconductor layer and are respectively located at two sides of the lower first gate, and the first source and the first drain are disposed oppositely, the upper first gate insulation layer is formed above the first source, the first drain, the first semiconductor layer, and the lower first gate insulation layer, the upper first gate is located above the upper first gate insulation layer, and the upper first gate and the lower first gate are directly opposite to each other.

8. The electrostatic discharge unit according to claim 3, wherein the two second gates are an upper second gate and a lower second gate, the second dual gate thin film transistor further includes a lower second gate insulation layer and an upper second gate insulation layer, and the lower second gate is deposited on the substrate of the array substrate, the lower second gate insulation layer is formed above the lower second gate, and the second semiconductor layer is formed above the lower second gate insulation layer, and projections of the second semiconductor layer and the lower second gate at a horizontal plane are overlapped, the second source and the second drain are located above the second semiconductor layer and are respectively located at two sides of the lower second gate, the two upper gate insulation layers are formed above the second source, the second drain, the second semiconductor layer, and the lower second gate insulation layer, the second gate is located above the upper second gate insulation layer, and the upper second gate and the lower second gate are directly opposite to each other.

9. An array substrate, comprising:
multiple scanning lines, and the multiple scanning lines are extended along a first direction;
multiple data lines, and the multiple data lines are extended along a second direction which is perpendicular to the first direction;
multiple common electrode lines, and the multiple common electrode lines are connected together;
multiple electrostatic discharge units, and the electrostatic discharge unit comprises;
a first branch including at least one first dual gate thin film transistor;
a second branch including at least one second dual gate thin film transistor;
wherein the first branch and the second branch are connected in parallel, a common first end point is electrically connected to a protection circuit, a common second end point is electrically connected to a common electrode line, and conduction directions of the first dual gate thin film transistor and the second dual gate thin film transistor are opposite.

10. The array substrate according to claim 9, wherein each first dual gate thin film transistor includes two first gates, one first semiconductor layer, one first source, and one first drain; on a longitudinal section, the first source, the first drain and the first semiconductor layer are located between the two first gates, and the two first gates and the first source of the same first dual gate thin film transistor are electrically connected together.

11. The array substrate according to claim 10, wherein each of the second dual gate thin film transistors includes two second gates, one second semiconductor layer, one second source and one second drain; on a longitudinal section, the second source, the second drain, and the second semiconductor layer are located between the two second gates, and the two second gates and the second source of a same second dual gate thin film transistor are electrically connected together.

12. The array substrate according to claim 11, wherein the first branch includes multiple first dual gate thin film transistors, the multiple first dual gate thin film transistors are connected in series, a first drain of a previous first dual gate thin film transistor and a first source of a next first dual gate thin film transistor are electrically connected; or
the second branch includes multiple second dual gate thin film transistors, the multiple second dual gate thin film transistors are connected in series, a second drain of a previous second dual gate thin film transistor and a second source of a next second dual gate thin film transistor are electrically connected.

13. The array substrate according to claim 11, wherein from the first end point, a first source of a first of the multiple first dual gate thin film transistors is electrically connected to the first end point, and a first drain of a last first dual gate thin film transistor is electrically connected to the second end point, a second drain of a first second dual gate thin film transistor is electrically connected to the first end point, and a second source of a last second dual gate thin film transistor is electrically connected to the second end point.

14. The array substrate according to claim 11, wherein the first gate and the first source of a same first dual gate thin film transistor are electrically connected through digging a hole; the second gate and the second source of a same second dual gate thin film transistor are electrically connected through digging a hole.

15. The array substrate according to claim 10, wherein the two first gates are an upper first gate and a lower first gate, the first dual gate thin film transistor further includes a lower first gate insulation layer and an upper first gate insulation layer, and the lower first gate is deposited on a substrate of the array substrate, the lower first gate insulation layer is formed above the lower first gate, the lower first gate insulation layer covers the lower first gate, and the first semiconductor layer is formed above the lower first gate insulation layer, and a projection of the first semiconductor layer and a projection of the lower first gate are overlapped at a horizontal plane, the first source and the first drain are located above the first semiconductor layer and are respectively located at two sides of the lower first gate, and the first source and the first drain are disposed oppositely, the upper first gate insulation layer is formed above the first source, the first drain, the first semiconductor layer, and the lower first gate insulation layer, the upper first gate is located above the upper first gate insulation layer, and the upper first gate and the lower first gate are directly opposite to each other.

16. The array substrate according to claim 11, wherein the two second gates are an upper second gate and a lower second gate, the second dual gate thin film transistor further includes a lower second gate insulation layer and an upper second gate insulation layer, and the lower second gate is deposited on the substrate of the array substrate, the lower second gate insulation layer is formed above the lower second gate, and the second semiconductor layer is formed above the lower second gate insulation layer, and projections of the second semiconductor layer and the lower second gate at a horizontal plane are overlapped, the second source and the second drain are located above the second semiconductor layer and are respectively located at two sides of the lower second gate, the two upper gate insulation layers are formed above the second source, the second drain, the second semiconductor layer, and the lower second gate insulation layer, the second gate is located above the upper second gate insulation layer, and the upper second gate and the lower second gate are directly opposite to each other,

17. A liquid crystal display panel, wherein the panel comprises the array substrate as claimed in claim 9.
